(19) United States
(12) Patent Application Publication
(10) Pub. No.: US 2026/0038567 A1
(43) Pub. Date: Feb. 5, 2026

(54) APPARATUSES AND METHODS FOR INDIVIDUALIZATION OF ACTIVATION COUNTER INITIALIZATION

(71) Applicant: Micron Technology, Inc., Boise, ID (US)

(72) Inventor: Keisuke Nomoto, Sagamihara-shi (JP)

(73) Assignee: Micron Technology, Inc., Boise, ID (US)

(21) Appl. No.: 19/270,189

(22) Filed: Jul. 15, 2025

Related U.S. Application Data
(60) Provisional application No. 63/677,769, filed on Jul. 31, 2024.

(51) Int. Cl. G11C 11/4072; G11C 11/406; G11C 11/408; G11C 11/4096

(52) U.S. Cl. CPC G11C 11/4072; G11C 11/40618; G11C 11/4085; G11C 11/4096

(57) ABSTRACT

Embodiments of the disclosure are drawn to apparatuses, systems, and methods for activation counter initialization (ACI) individualization. A memory may be placed in an ACI mode. During the ACI mode, an ACI control circuit sets the access count values of the memory array to an ACI flag value. When a word line is next accessed, the access count value associated with it may be initialized with an initialization value if the access count value is equal to the ACI flag value. The initialization value may be a random number, a pseudo-random number, or a deterministic number. By individually setting the initial state of the access count values at a time after the initial ACI mode, initialization may take less time.

### CROSS-REFERENCE TO RELATED APPLICATIONS

This application claims the filing benefit of U.S. Provisional Application No. 63/677,769, filed Jul. 31, 2024. This application is incorporated by reference herein in its entirety and for all purposes.

### BACKGROUND

Information may be stored on individual memory cells of the memory as a physical signal, such as a charge on a capacitive element. The memory may be a volatile memory and the physical signal may decay over time which may degrade or destroy the information stored in the memory cells. It may be necessary to periodically refresh the information in the memory cells by, for example, rewriting the information to restore the physical signal to an initial value.

As memory components have decreased in size, the density of memory cells has greatly increased. Repeated access to a particular memory cell or group of memory cells, often referred to as a “row hammer,” may cause an increased rate of data degradation in nearby memory cells. Memory devices use various schemes to identify addresses that are repeatedly accessed so that the nearby memory cells may be refreshed. One way to identify addresses that are repeatedly accessed is to keep a count of the number of accesses for a particular row. The count may need to be initialized to a starting value before the device begins to keep track of the number of accesses in a given time period. Memory devices may also use various schemes to initialize the count associated with a row such that initialization values do not cause false identification of attacks. It may be useful to decrease the predictability of the initialization values.

### BRIEF DESCRIPTION OF THE DRAWINGS

FIG. 1 is a block diagram of a semiconductor device according to at least one embodiment of the disclosure.

FIG. 2 is a block diagram of a memory cell array according to an embodiment of the present disclosure.

FIG. 3 is a block diagram of an activation counter initialization (ACI) control circuit that provides an ACI flag value and an initialization value to an access counter according to some embodiments of the present disclosure.

FIG. 4 is a block diagram of a portion of a memory device according to some embodiments of the present disclosure.

FIG. 5 is a flow chart of an example individual initialization operation according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory array includes a number of memory cells organized at the intersection of word lines, arranged as rows, and bit lines, arranged as columns. Information in the memory array may be accessed by one or more access operations, such as read or write operations. During an example access operation, a word line may be activated based on a row address. Information may be read from or written to selected memory cells along the active word line based on selected bit lines. Bit lines may be selected based on a column address. Information stored in the memory cells may decay over time. To prevent the loss of information, the memory array may periodically refresh the memory cells. For example, the memory cells may be refreshed on a row-by-row basis as part of a normal refresh and/or a self-refresh mode. The speed at which the rows are refreshed, or the maximum time any given row will go between refreshes, may be determined based on an expected rate of information decay.

Various patterns of access to a row may cause an increased rate of information decay in memory cells along nearby rows. A row experiencing such patterns of access may be called an aggressor row and the nearby rows may become victim rows. For example, a “row hammer” may involve repeated accesses to the aggressor row which may increase a rate of decay in adjacent rows and/or in rows which are farther away. This increased rate of decay, above the rate expected by the refresh timing, may risk the loss of information in the victim rows. Accordingly, some memories may track a number of accesses to each row to determine if they are aggressors so that victim rows can be identified and refreshed as part of a targeted refresh operation.

Counting accesses to each row may be referred to as a per row activation counter (PRAC) scheme. To implement such a scheme, each word line of a memory device has an associated access count value stored in counter memory cells along that word line. The access count value is used to determine how many times that word line has been accessed. When the word line is accessed the access count value may be changed, for instance incremented, by a counter circuit and compared to a mitigation threshold by a comparator. If the access count value crosses the mitigation threshold, then the address may be added to an aggressor queue and during targeted refresh operations, the addresses in the queue are used to generate refresh addresses.

There may be times when the counter memory cells have an unknown state. For example, after power up, the counter memory cells may be populated with random-like bits. If the memory is immediately used, the random state of the bits may create various issues, such as an illusion of an aggressor. An illusion of an aggressor may occur because some access count values start at a much higher value due to the random bits assigned at power up. To prevent an illusion of an aggressor, the memory device may initialize the counter memory cells with an initialization value. The initialization value may be such that it is known by the memory device or falls within a known range. There may be other situations which require initialization of the access counters, for example if refresh requirements are violated and the counters are placed in an unknown state. To prevent the random state of the access count values from causing undesired memory operations, the memory may initialize the access count values before memory operations begin or when the counters are in an unknown state.

During initialization the controller may provide one or more initialization commands. To save on the length of time this process takes, multiple count values may be initialized for each command. For example, some memories may use initialization schemes that write the same value to the counter memory cells of multiple word lines simultaneously. This scheme and others may cause the access count values to be potentially predictable and at higher risk of attack. However, it may not be practical to have every count value individually initialized during the initialization period, as that may be too time consuming. Accordingly, there may be a need to perform initialization at a later time when word lines can be individually accessed.

The present disclosure is drawn to apparatuses, systems, and methods for initializing access count values individually after activation counter initialization (ACI) operations. A memory may be placed in an ACI mode. The ACI mode may work through the array setting the access count values along each of the rows. In some embodiments, the specification for an example memory device may require that the ACI mode must be performed after a power up, or other reset, before the memory is available for access operations. During the ACI mode, an ACI control circuit may set the access count values of the memory array to an ACI flag value. In order to keep the amount of time the memory device spends in an ACI mode low, because no access operations may occur during the ACI mode, multiple word lines may be activated at a time and thus, multiple word lines may have their associated access count values set to the ACI flag value at a time. The ACI flag value may indicate that the access count value is ready to be set to an initialization value at a later time when the word line associated with the access count value is individually activated, such as for an access operation. After the ACI mode, in other words after the access count value is set to the ACI flag value, a counter control circuit may initialize the access count value to an initialization value when the row associated with the access count value, or ACI flag, is next accessed. The initialization value may be a random number, pseudo-random number, semi-random number, deterministic number, or combinations thereof. By initializing the access count values individually to an initialization value, the initialization values may be less predictable and thus, less prone to attacks, such as row hammer attacks. Because the value is initialized to an initialization value during normal operations after the ACI mode, the individual initialization of the initialization values may not add to the time required to complete the ACI mode.

In an example implementation, the memory may be placed in an ACI mode, for example based on a setting in a mode register, and during the ACI mode the memory may receive an ACI command. Responsive to that command, an ACI control circuit may provide internal ACI signals to other components of the memory, such as a row decoder and a counter control circuit. A row decoder activates one or more word lines associated with an ACI address and a counter control circuit writes an ACI flag value to the counter memory cells of the active word line responsive to an internal ACI signal. The ACI flag value may be a value that would be unnatural or unlikely to occur in the counter memory cells during access operations. For example, the ACI flag value may consist of setting all of the bits of the counter memory cells to “1” or the like. The purpose of setting the counter memory cells to the ACI flag value is to indicate to the counter control circuit to initialize the word line associated with the counter memory cells upon the next access of the word line.

After the ACI mode has ended, when a word line is accessed, the counter control circuit may check the value stored in the counter memory cells and if it matches the ACI flag value, a counter individualization circuit may initialize the access count value to an initialization value. The initialization value may be a random number, psuedo-random number, semi-random number, deterministic number, or combinations thereof. In some embodiments, the initialization value may be individualized for each word line. In other words, the initialization value may be different for every word line. In some embodiments, the counter control circuit may also increment the access count value after it is initialized to account for the access operation performed on the word line.

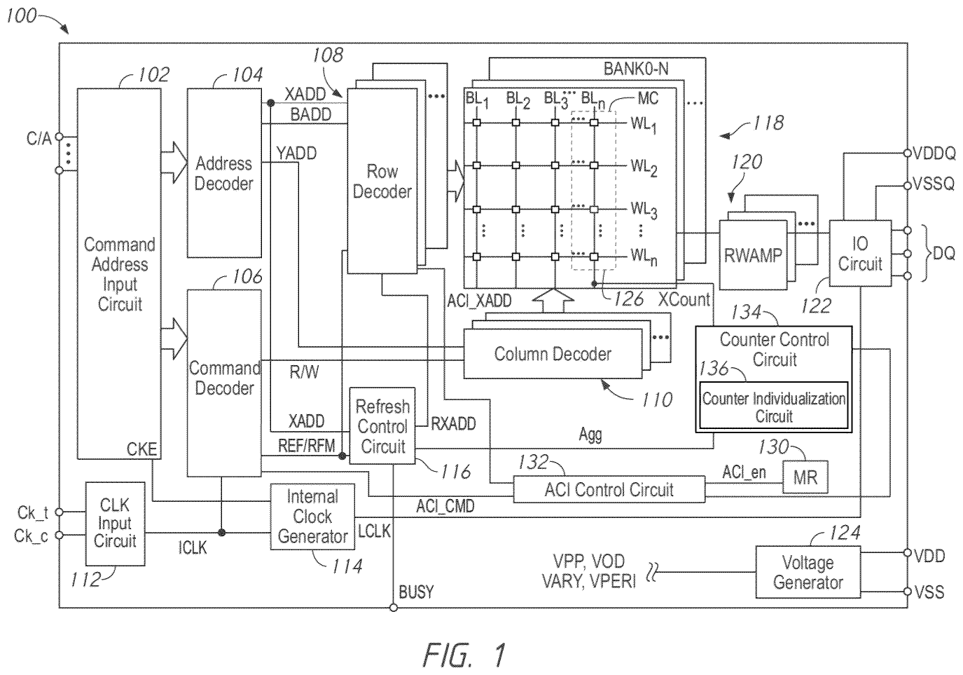

FIG. 1 is a block diagram of a semiconductor device according to at least one embodiment of the disclosure. The semiconductor device 100 may be a semiconductor memory device such as a DRAM device integrated on a single semiconductor chip.

The semiconductor device 100 includes a memory array 118. In the embodiment of FIG. 1, the memory array 118 is shown as including a number of memory banks, BANKO to BANKN. For example, the memory may include 4 banks, 8 banks, or 16 banks. More or fewer banks may be included in the memory array 118 of other embodiments. Each memory bank includes a plurality of word lines WL or rows, a plurality of bit lines BL or columns, and a plurality of memory cells MC arranged at intersections of the plurality of word lines WL and the plurality of bit lines BL.

The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank. The bit lines BL are coupled to a respective sense amplifier (not shown in FIG. 1). Read data from the bit line BL is amplified by the sense amplifier and transferred to read/write amplifiers 120 over complementary local data lines, transfer gate, and complementary main data lines. Conversely, write data outputted from the read/write amplifiers 120 is transferred to the sense amplifier over the complementary main data lines, the transfer gate, and the complementary local data lines, and written in the memory cell MC coupled to the bit line BL.

Some of the memory cells may be set aside as counter memory cells 126. The counter memory cells may store access count values XCount, each of which is associated with one of the word lines WL. Each access count value XCount may be stored in counter memory cells 126 along the word line WL with which the access count value XCount is associated. The access count value XCount may be stored as a binary number with each bit stored in a memory cell along the word line WL. For the sake of clarity, a single bit line of counter memory cells 126 is shown in FIG. 1. The number of counter memory cells 126 along each word line may be based on a number of bits of the access count value XCount. Extra counter memory cells 126, for instance more than the length of the number XCount, may be used. For example, extra counter memory cells 126 may store error correction information for the access count value XCount.

The counter memory cells 126 may be referred to as such because they are used for storing the access count values. The counter memory cells 126 may be structurally similar to, or identical to, the other memory cells of the array. The counter memory cells 126 may be grouped together, such as at the end of the word line WL. The counter memory cells 126 may be coupled along the same bit lines BL, which may be referred to as counter bit lines. Other distributions of the counter memory cells 126 along the word line WL may be used. The counter memory cells 126 may not be directly accessible by external devices such as controllers. The lack of direct access by external devices may be to prevent the access count values from being overwritten, for example. In other words, the counter bit lines may not be directly accessed by a normal column address.

The semiconductor device 100 may employ a plurality of external terminals to send and receive external signals. The plurality of external terminals include command and address C/A terminals coupled to a command and address bus to receive commands and addresses and a CS signal, clock terminals to receive clocks CK and/CK, data terminals DQ to provide data, and power supply terminals to receive power supply potentials VDD, VSS, VDDQ, and VSSQ.

The clock terminals are supplied with external clocks CK and/CK that are provided to an input circuit 112. The external clocks may be complementary. The input circuit 112 generates an internal clock ICLK based on the CK and/CK clocks. The internal clock ICLK is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line. When an access command is received, the command decoder 106 provides a row activation signal ACT, which activates the word line specified by the row address. At the end of an access operation, the command decoder 106 provides a pre-charge signal Pre, which pre-charges or deactivates the word line. When a row is activated, its access count value XCount is read out along the counter bit lines to a counter control circuit 134, which performs an access count update (ACU) operation that updates the access count value XCount to include the most recent access. An ACU operation may include reading the access count value XCount, updating the access count value such as by incrementing it, and writing the updated access count value back to the counter memory cells 126.

The semiconductor device 100 may receive an access command which is a read command. When a read command is received, a bank address BADD and a column address YADD are timely supplied with the read command, read data is read from memory cells in the memory array 118 corresponding to the row address XADD and column address YADD. The read command is received by the command decoder 106, which provides internal commands so that read data from the memory array 118 is provided to the read/write amplifiers 120. The row decoder 108 activates the word line indicated by XADD, and the information in the memory cells along that word line is read out to their respective bit lines. While the word line is activated, an ACU operation is performed. As in, the access count value XCount is read out to the counter control circuit 134, which updates the access count value XCount and writes it back to the counter memory cells along the active word line. The column decoder 110 provides a column select signal based on YADD which couples selected bit lines to the read/write amplifiers 120. A time after providing the activation signal, the row decoder 108 provides a pre-charge signal to deactivate the word line. The read data is outputted to outside from the data terminals DQ via the input/output circuit 122.

The semiconductor device 100 may receive an access command which is a write command. When the write command is received, a bank address BADD and a column address YADD are timely supplied with the write command, write data supplied to the data terminals DQ is written to memory cells in the memory array 118 corresponding to the row address and column address. The write command is received by the command decoder 106, which provides internal commands so that the write data is received by data receivers in the input/output circuit 122. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cell MC. The row decoder 108 provides the activation signal to the word line indicated by XADD, which causes the values in the memory cells along the active word line to be read out to their respective bit lines. An ACU operation may be performed, such that the access count value XCount along the activated word line is read out to the counter control circuit 134 which updates the access count value XCount and writes it back. The column decoder 110 provides a column select signal based on YADD and couples selected bit lines to the read/write amplifiers 120, which write the write data onto the selected bit lines. A time after activating the row, the row decoder 108 provides a pre-charge signal and deactivates the word line.

The semiconductor device 100 may also receive commands causing it to carry out refresh operations. For example, a controller of the memory may put the semiconductor device 100 into a normal refresh mode and provide a refresh command. Responsive to the refresh command, the command decoder 106 provides a refresh signal REF. The semiconductor device 100 may also enter a self-refresh mode where the refresh signal REF is generated internally.

Responsive to the refresh signal REF, the refresh control circuit 116 performs one or more refresh operations by providing a refresh address RXADD, along with refresh signals (not shown in FIG. 1) to the row decoder 108. The row decoder 108 refreshes the word line(s) associated with the refresh address RXADD, for example by restoring a charge in the memory cells along the word line(s) to an initial value associated with the value of the bit stored in that memory cell.

When the refresh control circuit 116 performs refresh operations responsive to REF, it determines if the refresh operations are normal refresh operations, targeted refresh operations, or combinations thereof. In a normal refresh operation, the refresh address RXADD is generated based on a sequence of addresses. In other words, the refresh address RXADD may be generated based on a previous value of the refresh address. For example, RXADD(i)=RXADD(i−1)+1. The sequence logic used to generate the normal refresh addresses may cycle through each of the word lines of the memory array 118. For instance, the refresh control circuit 116 may include an address counter and an address mapping circuit. The address counter may count through a sequence of values and the address mapping circuit may generate the refresh address RXADD based on the position of the count in the sequence.

In a targeted refresh operation, the refresh address RXADD is generated based on an identified aggressor address stored in a targeted refresh queue of the refresh control circuit 116. The refresh address RXADD may represent victim addresses, which may be associated with word lines that have a spatial relationship with the word line associated with the identified aggressor address. For example, the refresh address RXADD may be word lines adjacent to the aggressor word line (e.g., RXADD=Aggressor+/−1). Other relationships (e.g., +/−2, +/−3, +/−4, etc.) may also be used.

In some embodiments, the normal refresh address may be associated with a different number of word lines than the targeted refresh address. The normal refresh address may be associated with more word lines than the targeted refresh address. For example, the normal refresh address may be truncated compared to a row address XADD and be associated with all the word lines whose addresses share the value of that truncated portion in common, while the targeted refresh address may be associated with a single word line.

The counter control circuit 134 may act as an aggressor detection circuit, which tells the refresh control circuit 116 if the current row address XADD is associated with an aggressor word line or not. For example, if the updated access count value XCount from the currently active word line crosses a mitigation threshold, then the counter control circuit 134 may provide an aggressor detected signal Agg to the refresh control circuit 116. Responsive to the aggressor detected signal Agg, the refresh control circuit 116 adds the current row address XADD to the targeted refresh queue. The counter control circuit 134 may include a comparator which compares the updated access count value XCount to the mitigation threshold. Alternatively, the counter control circuit 134 may inherently act as a comparator. For example, the threshold may represent the maximum value of the access count value XCount and when the access count value XCount reaches a maximum value and “rolls over” back to an initial value, the counter control circuit 134 provides an aggressor detected signal Agg.

During an ACI mode, the device 100 may set the access counts XCount of the memory array 118 to an ACI flag that indicates the access counts XCount are ready for initialization. A controller of the memory may put the semiconductor device 100 into an ACI mode and, if applicable, provide an ACI command. In some embodiments, the semiconductor device 100 may enter an ACI mode automatically, such as after power up. Based on an ACI command or based on internal timing, the command decoder 106 provides an ACI command signal ACI_CMD.

Responsive to the ACI command signal ACI_CMD, the ACI control circuit 132 provides an ACI address ACI_XADD, along with other ACI signals (not shown in FIG. 1) to the row decoder 108 and provides ACI signals ACI to the counter control circuit 134. The row decoder 108 activates the word line(s) associated with the ACI address ACI_XADD. Responsive to the ACI signal ACI, when a word line is activated, the counter control circuit 134 sets the counter memory cells along the active word line(s) by writing an ACI flag value to the counter memory cells associated with the activated word line(s). In some embodiments, the ACI flag value may be an unnatural count value, such as setting all of the counter bits to “1” or setting the bits with alternating “1's” and “0's.” The ACI flag value written to the access count value XCount may be the same for every word line. The ACI operations may be repeated until all the access count values XCount of the memory array 118 are set to the ACI flag value.

The semiconductor device 100 may include a counter individualization circuit 136 to initialize the counter memory cells 126 that contain the ACI flag when the associated row is accessed. The counter individualization circuit 136 may, in some embodiments, be included in the counter control circuit 134. Responsive to an access command, such as an activation command ACT or a pre-charge command PRE, the counter individualization circuit 136 may read the value stored in the counter memory cells 126 associated with the word line WL accessed by the access command. If the value stored in the counter memory cells 126 matches the ACI flag value, the counter individualization circuit 136 will write an initialization value to the counter memory cells 126. In some embodiments, the initialization value may be a random number, pseudo-random number, semi-random number, deterministic number, or combinations thereof. Because the initialization value is written when the word line is accessed, only a single word line will be active, as opposed to during the ACI mode, when several word lines are active at once. This allows for the PRAC to be individually modified. For example, in some embodiments, each word line WL may have a different initialization value written to its respective counter memory cells 126. After initialization, the access count value may be incremented to account for the access operation that triggered initialization, for example by an ACU operation. If the counter memory cells 126 do not contain an ACI flag when read by the counter individualization circuit 136 responsive to an access command, the counter individualization circuit 136 will preform and ACU operation and cause the access count value XCount stored in the counter memory cells to be updated, for example incremented.

The semiconductor device 100 includes one or more registers where information and/or settings of the semiconductor device 100 are stored. For example, FIG. 1 shows a mode register 130, which includes a number of registers which may be used to store settings, properties, measured quantities, etc. related to the operation of the semiconductor device 100. The mode register may be organized into registers, which may be organized into sub-units such as operation codes, or op-codes. A controller of the semiconductor device 100 may access specified registers, or op-codes, by performing mode register read or write operations. Some registers, or op-codes, may be read-only. The memory device 100 may also retrieve information from the mode register and change information in the mode register 130.

As discussed herein, the semiconductor device 100 may be placed in an ACI mode. For example, an ACI register of the mode register 130 may have a value which indicates if the device is in the ACI mode or not. If the register is set to an inactive state, then the device is not in an ACI mode and is in a normal operational mode. If the register is set to an active state, then the device is in an ACI mode. When the device is in an ACI mode, access operations to the memory device may be restricted or prevented. For example, while the ACI register is active, the controller may be prevented from accessing the memory array 118.

As well as enabling the ACI mode, the mode register may include various other registers, or portions thereof, useful for managing the ACI mode and ACI operations. For example, the mode register 130 may include an ACI status indicator. The ACI control circuit 132 may update the status indicator in the mode register 130 to indicate when ACI operations are complete, or in other words all access count values have been flagged for individual initialization during an ACI mode. A controller may monitor the status indicator and deactivate the ACI mode when the status indicator changes to indicate that ACI operations are complete. In some embodiments, the register which enables the ACI mode may be dependent on one or more other settings. For example, if PRAC is not enabled on the device by a PRAC register, then it may not be possible to enable an ACI mode as the counter values are not used, and thus initialization would serve no purpose.

The power supply terminals are supplied with power supply potentials VDD and VSS. The power supply potentials VDD and VSS are supplied to an internal voltage generator circuit 124. The internal voltage generator circuit 124 generates various internal potentials VPP, VARY, VPERI, and the like based on the power supply potentials VDD and VSS supplied to the power supply terminals. The internal potential VPP is mainly used in the row decoder 108, the internal potentials VARY are mainly used in the sense amplifiers SAMP included in the memory array 118, and the internal potential VPERI is used in many peripheral circuit blocks.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

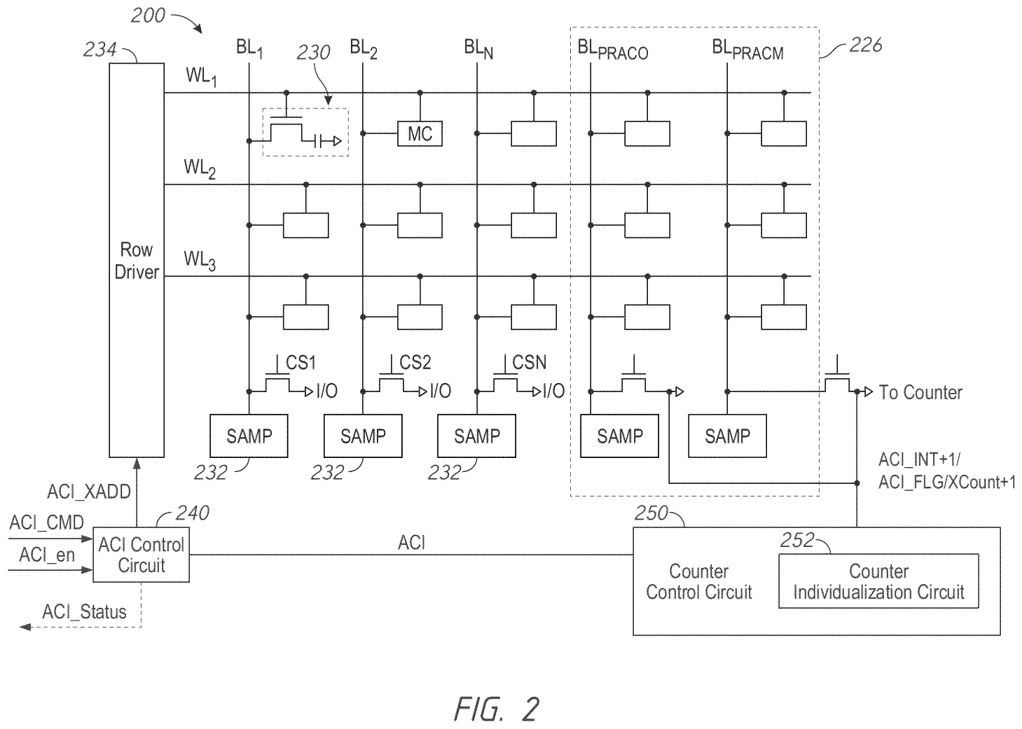

FIG. 2 is a block diagram of a memory cell array according to an embodiment of the present disclosure. The memory cell array 200 may represent an exemplary portion of a memory array, such as the memory array 118 of FIG. 1. The memory cell array 200 includes a plurality of word lines WL, or rows, and bit lines BL, or columns. A row decoder 234 (e.g., row decoder 108 of FIG. 1) is coupled to the rows. A plurality of memory cells MC, such as example memory cell 230, are located at the intersection of the rows and columns. Some of the memory cells may be set aside as counter memory cells 226 (e.g., counter memory cells 126 of FIG. 1). The memory array 200 includes a number of sense amplifiers 232.

Each of the memory cells MC may store information. In some embodiments, the information may be stored as a binary code and each memory cell MC may store a bit that may be either at a logical high or a logical low level. Example memory cell 230 shows a particular implementation which may be used to store a bit of information in some embodiments. Other types of memory cells may be used in other examples. In the example memory cell 230, a capacitive element stores the bit of information as a charge. A first charge level may represent a logical high level, while a second charge level may represent a logical low level. One node of the capacitive element is coupled to a reference voltage (e.g., VSS). The other node of the capacitive element is coupled to a switch. In the example memory cell 230, the switch is implemented using a transistor. A sense node of the switch, such as the gate of the transistor, is coupled to the word line WL. The word line WL may be accessed by the row driver 234 setting a voltage along the word line such that the switches in the memory cells MC are closed, coupling the capacitive elements, or other bit storage element, to the associated bit lines BL.

The sense amplifiers 232 may read or write a value of a bit of information along the bit line BL to memory cell(s) MC at the accessed word line WL. The sense amplifiers 232 may convert a signal along the bit line BL to a signal which is “readable” by other elements of the memory device, such as by amplifying a voltage. The bit lines BL may be coupled to an input/output circuit (e.g., input/output circuit 122 of FIG. 1) via a respective column select switch, which may be a column select transistor activated by a column select signal CS. In the example view of FIG. 2, bit lines BL₁-BL_{N} are “normal” bit lines BL₁-BL_{N}, each accessed by a respective column select signal CSI to CSN, and bit lines BL_{PRAC0}-BL_{PRACM} are associated with the counter memory cells 226. Accordingly, each word line WL of FIG. 2 stores N+M total bits, M of which are designated for an access count value (e.g., XCount of FIG. 1). It should be understood that FIG. 2 is a simplified view and that many more or fewer memory cells and/or a different ratio of normal memory cells to counter memory cells 226 may be used.

In an example read operation, when a word line WL is accessed, the memory cells MC may provide their charge onto the coupled bit lines BL which may cause a change in a voltage and/or current along the bit line BL. The sense amplifier 232 may determine a logical level of the accessed memory cell MC based on the resulting voltage and/or current along the bit line BL and may provide a signal corresponding to the logical level through the column select transistor to the input/output circuit.

In an example write operation, the sense amplifiers 232 may receive a signal indicating a logical level to be written to the accessed memory cells from the input/output circuit. The sense amplifier 232 may provide a voltage and/or current along the coupled bit line BL, such as along the bit lines BL with active column select transistors, at a level corresponding to the logical level to be written. The voltage and/or current along the bit line BL may charge the capacitive element at the intersection of the bit line BL with an accessed word line WL to a charge level associated with the written logical level. In this manner, by specifying the row which is accessed and which bit lines BL to record data from (and/or write data to), specific memory cells MC may be accessed during one or more operations of the memory device.

During an example refresh operation, either targeted or normal refresh, the word line WL to be refreshed may be read and then a logical value read from each of the memory cells along that word line WL may be written back to the same memory cells. In this manner the level of charge in the refreshed memory cells MC may be restored to the full value associated with the logical level stored in that memory cell.

During an example ACI operation, an ACI control circuit 240 (e.g., ACI control circuit 132 of FIG. 1) receives an ACI command signal ACI_CMD. In some embodiments the ACI_CMD may be received along with an ACI enable signal ACI_en. The ACI enable signal ACI_en indicates if the memory device is in an ACI mode or not. For example, the ACI enable signal ACI_en may be provided by a mode register such as 130 of FIG. 1. The ACI command signal ACI_CMD may be provided by a command decoder such as 106 of FIG. 1. In some embodiments, the ACI command signal ACI_CMD may be a command used for another purpose outside the ACI mode, such as a refresh command, which is interpreted as an ACI command when the device is in the ACI mode, such as when ACI_en is active.

Responsive to the ACI command signal ACI_CMD and when the enable signal ACI_en is active, the ACI control circuit 240 performs an ACI operation by providing an ACI address ACI_XADD, along with ACI signals (not shown in FIG. 2), to the row decoder 234. The row decoder 234 activates the word line(s) WL associated with the ACI address ACI_XADD. Also, responsive to the ACI command signal ACI_CMD when the enable signal ACI_en is active, the ACI control circuit 240 performs an ACI operation by providing an ACI signal ACI to the counter control circuit 250 (e.g., counter control circuit 134 of FIG. 1). Responsive to the ACI signal ACI, the counter control circuit 250 provides an ACI flag value ACI_FLG to the sense amplifier 232 coupled to the counter memory cells 226. The sense amplifier 232 drives the ACI flag value ACI_FLG on to the counter memory cells 226 of the active word lines WL. In this manner, the ACI flag value may be written to multiple word lines WL at a time. An address counter may be coupled with the ACI control circuit 240 that provides the ACI address to the row decoder 234. The address counter may be a component that is shared with an existing system, such as the refresh control circuit. For example, the address counter may be an address counter which is used to generate refresh addresses when the device is not in the ACI mode. The ACI operation is a write only operation.

In some embodiments, the counter control circuit 250 may include a counter individualization circuit 252 (e.g., 136 of FIG. 1) to initialize the counter memory cells 126 that contain an ACI flag when they are individually accessed and the memory device (e.g., 100 of FIG. 1) is not in an ACI mode. The counter individualization circuit 252 (e.g., 136 of FIG. 1), responsive to an access command such as an activation command ACT or a pre-charge command PRE, may read the value stored in the counter memory cells 226 (e.g., 126 of FIG. 1) associated with the word line WL accessed by the access command. If the value stored in the counter memory cells 226 (e.g., 126 of FIG. 1) matches an ACI flag value, the counter individualization circuit 252 (e.g., 136 of FIG. 1) will write an initialization value ACI_INT to the counter memory cells 226 (e.g., 126 of FIG. 1). After the initialization value ACI_INT is written to the counter memory cells 226 (e.g., 126 of FIG. 1), the counter control circuit 250 (e.g., 134 of FIG. 1) may perform an ACU operation and increment the value stored in the counter memory cells 226 (e.g., 126 of FIG. 1) to account for the activation that triggered the initialization. For example, the ACU operation may cause an updated value of ACI_INT+1 to be written to the counter memory cells 226 (e.g., 126 of FIG. 1). During an ACU operation, the value stored in the counter memory cells 226 (e.g., 126 of FIG. 1) is read out, updated, and written back. If the value stored in the counter memory cells 226 does not equal the ACI flag value, the counter control circuit 320 may increment the access count value XCount+1 and write it back to the counter memory cells 226.

Responsive to the ACI address ACI_XADD and ACI signals, the row driver 234 may begin to activate the word lines WL of a memory array 200 one-by-one. After an amount of time, beginning when the word line WL is activated, the row decoder 234 may deactivate each word line WL, for example with a pre-charge signal PRE. An activation time delay may be implemented to determine when a subsequent word line WL is activated. During normal operations, such as when the device is not in the ACI mode, the time delay may be used to prevent two word lines that are coupled to the same sense amplifiers from being active at the same time. For example, the delay may be set to ensure that the first word line pre-charges before the next word line activates. In some embodiments, during the ACI mode, the activation time delay may be shortened such that a subsequent word line WL is activated before the currently active word line WL deactivates, i.e., pre-charges. In this manner, two word lines in a same section may both be active at the same time during an ACI mode.

The ACI control circuit 240 may provide a signal, such as a status signal ACI_status, to indicate that the ACI mode may end. For example, the ACI control circuit 240 may monitor a number of ACI_CMDs and when a specified number of ACI_CMDs are received, the ACI control circuit 240 provides the signal ACI_status. In another example, the address counter may be used and when the address counter recycles to an initial value, indicating that all word lines have been refreshed, the ACI control circuit 240 provides ACI_status. The value of ACI_status may be written to a register, such as in mode register 130 of FIG. 1, and used as an indicator that the ACI operations are done. Responsive to ACI_status being active, the controller may end the ACI mode, for example by resetting ACI_en.

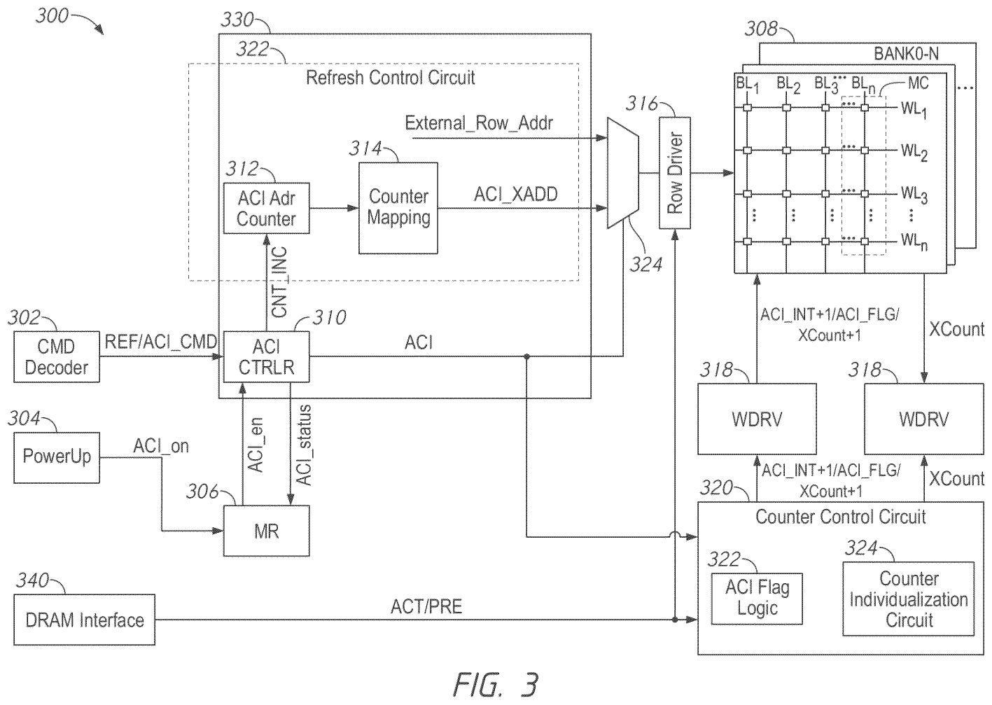

FIG. 3 is a block diagram of an ACI control circuit that provides an ACI flag value and an initialization value to an access counter according to some embodiments of the present disclosure. The ACI control circuit 330 may implement the ACI control circuit 132 of FIG. 1 and/or 240 of FIG. 2. The dotted line around the refresh control circuit 322 is shown to represent that each of the components within the dotted line may be unique to the ACI control circuit 330 or may be shared with another circuit of the memory device, such as a refresh control circuit (e.g., 116 of FIG. 1). For example, the ACI address counter 312 may be an existing address counter component belonging to the refresh control circuit.

While in an ACI mode, an ACI controller 310 receives an ACI command signal ACI_CMD from a command decoder 302 (e.g., command decoder 106 of FIG. 1) and receives an ACI enable signal ACI_en from a mode register 306 (e.g., mode register 130 of FIG. 1). The ACI enable signal ACI_en indicates if the memory device is in an ACI mode or not. The memory device may be automatically placed in an ACI mode after power up and an internal ACI mode signal ACI_on may be provided to the mode register 306. A controller may perform a mode register write operation to set the value ACI_en to an active state. When the device is in the ACI mode, access operations to the memory device may be restricted or prevented. For example, while the value ACI_en in the mode register 306 is active, the controller may be prevented from accessing the memory array 308. Similarly, other operations may also be modified by the ACI mode being active. For example, while ACI_en is active refresh operations may not be performed, because the ACI mode must occur before normal memory operations, and thus there is no data to protect in the array 308.

Responsive to the ACI command signal ACI_CMD when the ACI enable signal ACI_en is active, the ACI controller 310 performs an ACI operation by providing an address count increment signal CNT_INC to the ACI address counter 312. The ACI address counter 312 provides a signal to the counter mapping circuit 314 which provides an ACI address ACI_XADD to the row driver 316 (e.g., row decoder 108 of FIG. 1 and/or row driver 234 of FIG. 2). The ACI address ACI_XADD may correspond to a single word line address or multiple word line addresses. For example, the ACI address may be truncated compared to a full row address XADD, and the ACI address may be associated with every word line which is addressed by the truncated portion. The row decoder 316 activates a word line or word lines according to the ACI address ACI_XADD. The ACI address counter 312 and the counter mapping circuit 314 may be existing components of a refresh control circuit such as 116 of FIG. 1.

While the ACI enable signal ACI_en is active, the ACI controller 310 provides an ACI signal ACI to the counter control circuit 320 (e.g., counter control circuit 134 of FIG. 1 and/or counter control circuit 250 of FIG. 2). When the ACI signal ACI is received, the counter control circuit 320 may operate differently than during a “normal” mode. For example, when the device is in the ACI mode, the counter control circuit 320 may only perform write operations to initialize the counter memory cells but in the “normal” mode, the counter control circuit 320 may perform read-modify-write operations to read the count value, modify it such as by incrementing it, and then write the modified value back.

Responsive to the ACI signal ACI during an ACI mode, the counter control circuit 320 may set the access count values XCount of the counter memory cells to an ACI flag value ACI_FLG. The ACI flag value ACI_FLG indicates to the counter control circuit 320 (e.g., 134 of FIG. 1 and/or 250 of FIG. 2) that the counter memory cells are ready to receive an initialization value ACI_INT when the word line associated with the counter memory cells is next accessed. The counter control circuit 320 (e.g., 134 of FIG. 1 and/or 250 of FIG. 2) may include an ACI flag circuit 322 that provides an ACI flag value ACI_FLG to the write driver 318 coupled to the counter memory cells of the memory array 308 (e.g., memory array 118 of FIG. 1). When a word line is activated by the row decoder 316 during an ACI mode, such as responsive to ACI_XADD, the write driver 318 then writes the ACI flag value ACI_FLG to the counter memory cells of the activated word lines of the memory array 308. For example, the write driver 318 may fire the sense amplifiers (e.g., 232 of FIG. 2) of the memory array 308 and drive the ACI flag value ACI_FLG onto the counter bit lines.

The ACI flag value ACI_FLG may be an unnatural counter value in order to indicate that the counter memory cells have undergone an ACI operation and require an initialization value when next accessed. The unnatural counter value may be any value that the counter is unlikely to reach during regular operation of the memory device. In some embodiments, the ACI flag value ACI_FLG may require setting each bit of the counter memory cells to the opposite value of the adjacent bits. For example, alternating “1” and “0” values in the bits of the counter memory cells. In some embodiments, the ACI flag value ACI_FLG may consist of setting all of the bits of the counter memory cells to “1.”

After setting the ACI flag for an address, the ACI controller 310 may provide a count increment signal CNT_INC to the ACI address counter 312. The ACI address counter 312 provides a signal to a counter mapping circuit 314 which in turn provides a next ACI address ACI_XADD to the row decoder 316. The row decoder then activates the next word line or word lines of the memory array 308, such as by incrementing the address. The next word line may activate before the previous word line deactivates, i.e., pre-charges.

The ACI controller 310 may also provide an ACI status signal ACI_status to the mode register 306 to indicate the completion of the ACI operation. For example, the address counter 312 and/or counter mapping circuit 314 may provide a signal (not shown) which indicates that all count values have received an ACI flag value, in other words indicating that each unique value of ACI_XADD has been generated, and/or the ACI controller 310 may count a number of times that ACI_CMD is received. Responsive to the ACI status signal ACI_status, the mode register may set the ACI enable register value ACI_en to an inactive state so the device is not in an ACI mode or is in a normal operational mode. In some embodiments, a controller may monitor ACI_status during the ACI mode, such as by performing mode register read operations on ACI_status. Once ACI_status changes, the controller may perform a mode register write operation to change a status of ACI_en to inactive and end the ACI mode.

The mode register 306 may include various settings which are used to enable the ACI mode and control the operation thereof. For example, the ACI enable and status registers may be op-codes within a register set aside for PRAC. The register MR70 may include information related to PRAC such as a first op-code OP[1] which enables or disables the use of access counts, for example enables or disables the PRAC feature, a second op-code OP[2] which acts as ACI_en, and a third op-code OP[3] which acts as ACI_status. In some embodiments, the op-codes may be single-bit values which are set to either inactive (0 or 0_{B}) or active (1 or 1_{B}). Other mode registers and/or op-codes may be used in other example implementations. A controller, or host, of the memory may interact with the mode register 306 to enable and disable the ACI mode.

Like normal DRAM cells, the Activation Counter bits require refresh to maintain the stored values. Any time refresh is violated during the ACI operation or after the ACI operation in modes like MPSM or other idle periods, the ACI operation may be performed by the host to set the Activation Counter bits to a known state. Because array data is also corrupted by refresh violations, previous access count values, or Activation Counter values, become irrelevant.

Responsive to an access command and ACI mode being disabled, such as an activation command ACT or a pre-charge command PRE, a counter individualization circuit 324 (e.g., 136 of FIG. 1 and/or 252 of FIG. 2) may individually initialize the counter memory cells 126 that contain an ACI flag with an initialization value. The counter individualization circuit 136 may, in some embodiments, be included in the counter control circuit 320 (e.g., 134 of FIG. 1 and/or 250 of FIG. 2). Responsive to an access command, the counter individualization circuit 324 (e.g., 136 of FIG. 1 and/or 252 of FIG. 2) may read the value stored XCount in the counter memory cells associated with the word line WL accessed by the access command. In some embodiments, the access command may be an activation command ACT. In some embodiments, the access command may be a pre-charge command PRE. The activation count value XCount may be read from the read driver 328 of the memory device. If the activation count value XCount stored in the counter memory cells matches an ACI flag value ACI_FLG, for example all “1”s, the counter individualization circuit 324 (e.g., 136 of FIG. 1 and/or 252 of FIG. 2) will write an initialization value ACI_INT to the counter memory cells. In some embodiments, the initialization value ACI_INT may be a random value and, in some embodiments, it may be a pre-determined value. Each word line WL may have a different, or individualized, initialization value written to its respective counter memory cells. In some embodiments, the counter control circuit 320 (e.g., 134 of FIG. 1 and/or 250 of FIG. 2) may perform an ACU operation or iterate the access count value XCount, now equal to an initialization value ACI_INT, to account for the access operation. For example, the counter control circuit 320 (e.g., 134 of FIG. 1 and/or 250 of FIG. 2) will increment the access count value XCount/ACI_INT to be, for example, XCount+1/ACI_INT+1. If the counter memory cells do not contain an ACI flag when read by the counter individualization circuit 324 (e.g., 136 of FIG. 1 and/or 252 of FIG. 2) responsive to an access command, the counter individualization circuit 324 will cause the access count value XCount stored in the counter memory cells to be incremented and written back.

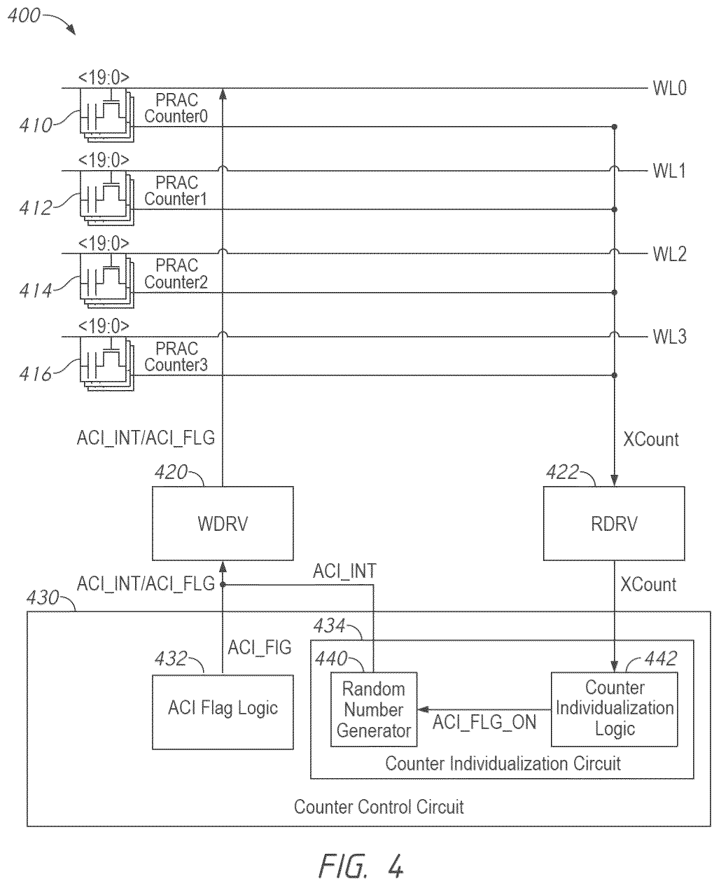

FIG. 4 is a block diagram of a portion of a memory device according to some embodiments of the present disclosure. In some embodiments, the counter memory bits 410, 412, 414, and 416 may be an implementation of counter memory cells 126 of FIG. 1 and/or 226 of FIG. 2. In some embodiments, the counter control circuit 430 may be an implementation of counter control circuit 134 of FIG. 1, 250 of FIG. 2, and/or 320 of FIG. 3.

The counter control circuit 434 may include an ACI flag circuit 432 (e.g., 322 of FIG. 3). During an example ACI operation, the ACI address, e.g., ACI_XADD, provided to the row decoder (e.g., 316 of FIG. 3), may truncate one or more bits in order to activate more word lines simultaneously. In some embodiments, each word line WL<0>through WL<3>shown in FIG. 4 may represent multiple word lines. The ACI flag circuit 432 (e.g., 322 of FIG. 3) may drive an ACI flag value ACI_FLG on to the activated word line(s), for example using a write driver 420 (e.g., 318 of FIG. 3). The ACI flag value ACI_FLG may be an unnatural counter value. For example, the ACI flag value ACI_FLG may be a value of “1” in every bit of the counter memory cells 410, 412, 414, and 416.

Each word line may be coupled to a read driver 442 (e.g., 328 of FIG. 3). In some embodiments, responsive to an access command, the read driver 442 (e.g., 328 of FIG. 3) may read out an activation count value XCount to a counter individualization logic circuit 442 (e.g., 136 of FIG. 1, 252 of FIG. 2, and/or 324 of FIG. 3). If the activation count value XCount read out to the counter individualization logic circuit 442 is equal to an ACI flag value ACI_FLG, then, in some embodiments, the counter individualization logic circuit 442 may transmit an ACI flag on ACI_FLG_ON signal to an ACI flag logic circuit 440 (e.g., 322 of FIG. 3). In some embodiments, the ACI flag logic circuit 440 (e.g., 322 of FIG. 3) may be a random number generator. Responsive to the ACI flag on ACI_FLG_ON signal, the random number generator 440 may generate and transmit a random initialization value ACI_INT to the write driver 420 which may, in turn, drive the initialization value ACI_INT on to the counter memory cells 410, 412, 414, and/or 416 of the active word line(s). It should be noted that the random number generator 440 may produce pseudo-random numbers as ACI initialization values due to the complexity of the circuitry required to produce truly random numbers.

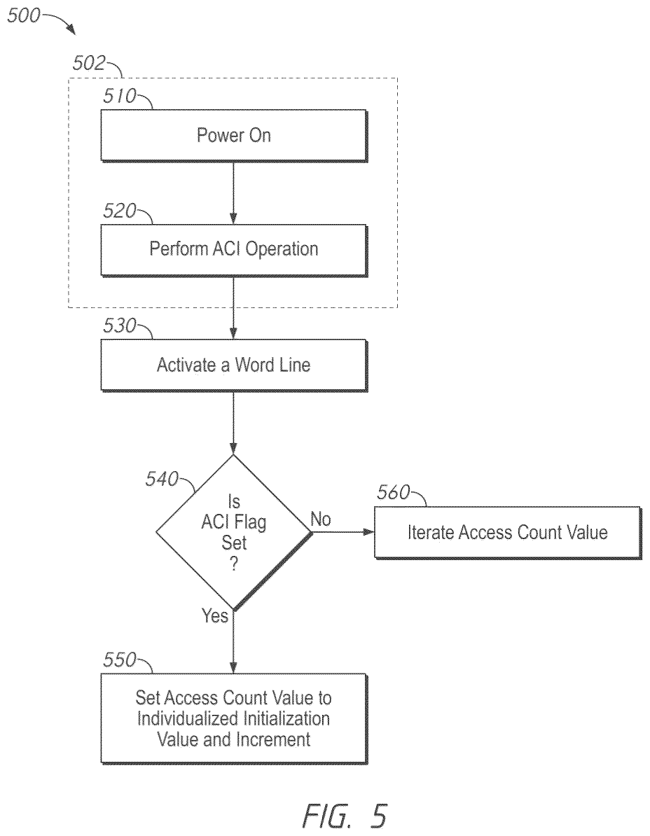

FIG. 5 is a flow chart of an example individual initialization operation according to some embodiments of the present disclosure. The flow chart 500 of FIG. 5 may, in some embodiments, be implemented by one or more of the apparatuses or systems described herein. For example, method 500 may be performed by the semiconductor device 100 of FIG. 1 and/or the counter control circuit 134 of FIG. 1, 250 of FIG. 2, 324 of FIG. 3, and/or 430 of FIG. 4 during an individual initialization operation.

The method 500 may include box 510, which describes powering on a memory device. For example, the method 500 may include waking a memory device (e.g., 100 of FIG. 1) from a standby mode or an initial power reception of a memory device (e.g., 100 of FIG. 1) that was off. The power may, for example, be received by the memory device (e.g., 100 of FIG. 1) a voltage terminals VDD and/or VSS.

Box 510 is followed by box 520, which describes putting the memory device in an ACI mode. During an ACI mode, the device may write an ACI flag value ACI_FLG to the counter memory cells along the accessed word line, for example, by sending an ACI signal ACI to the counter control circuit (e.g., 134 of FIG. 1, 250 of FIG. 2, 324 of FIG. 3, and/or 430 of FIG. 4). The ACI flag value may be a single value written to all counter memory cells or it may be different values. The ACI flag value may be an unnatural counter value. For example, the ACI flag value may be setting all of the bits to “1.” Steps 510 and 520 may be optional and may not occur during every initialization operation as depicted by the dashed box 502 because initialization may happen at any time after an ACI mode, not just after power up.

Box 520 is followed by box 530, which describes activating a word line. The word line may be activated by an access command, such as an activation command ACT and/or a pre-charge command PRE. The access command may be transmitted by a DRAM interface, such as 340 of FIG. 3.

Box 530 is followed by box 540, which describes determining whether the counter memory cells have been set to an ACI flag value. During an ACI mode, the access count value stored in the counter memory cells (e.g., 126 of FIG. 1, 226 of FIG. 2, and/or 410, 412, 414, 416 of FIG. 4) may be set to an ACI flag value, such as all “1”s. The counter control circuit (e.g., 134 of FIG. 1, 250 of FIG. 2, 324 of FIG. 3, and/or 430 of FIG. 4) may check the access count value XCount for the ACI flag value. For example, a counter individualization logic circuit (e.g., 136 of FIG. 1, 252 of FIG. 2, 324 of FIG. 3, and/or 442 of FIG. 4) may read out the access count value XCount. If the access count value XCount matches the ACI flag value, the method 500 will proceed to box 550.

Box 550 describes setting an access count value XCount to an initialization value and incrementing it. The initialization value may be a pre-determined value or it may be a random value. In some embodiments, the initialization value may be generated by a random number generator such as 440 of FIG. 4 responsive to an ACI flag on indication from the a counter individualization logic circuit 442 (e.g., 136 of FIG. 1, 252 of FIG. 2, and/or 324 of FIG. 3). After setting the access count value XCount to the initialization value, the counter control circuit (e.g., 134 of FIG. 1, 250 of FIG. 2, 324 of FIG. 3, and/or 430 of FIG. 4) may increment the access count value XCount to account for the access command. In other words, the counter control circuit (e.g., 134 of FIG. 1, 250 of FIG. 2, 324 of FIG. 3, and/or 430 of FIG. 4) may write a value of the initialization value plus 1 back to the counter memory cells (e.g., 126 of FIG. 1, 226 of FIG. 2, and/or 410, 412, 414, 416 of FIG. 4).

If the access count value XCount is found at box 540 to not match the ACI flag value, the method 500 will proceed to box 560. Box 560 describes iterating the access count value XCount stored in the counter memory cells (e.g., 126 of FIG. 1, 226 of FIG. 2, and/or 410, 412, 414, 416 of FIG. 4). In some embodiments, iterating the access count value XCount may comprise incrementing the access count value XCount. For example, if the ACI flag value is not stored in the counter memory cells, then the memory device has not entered an ACI mode between the last access of the activated word line(s) and the current activation and the counter control circuit accounts for the activation by incrementing the access count value XCount in order to maintain a count of the activations that take place on each word line. The updated access count value XCount may then be written back to the counter memory cells (e.g., 126 of FIG. 1, 226 of FIG. 2, and/or 410, 412, 414, 416 of FIG. 4). The method 500 may repeat with each activation of a word line.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a word line coupled to a plurality of memory cells, wherein a portion of the plurality of memory cells are counter memory cells configured to store an access count value associated with a number of times the word line is accessed; and
a counter control circuit configured to set the access count value to an activation counter initialization (ACI) flag value as part of an ACI mode, the counter control circuit comprising a counter individualization circuit configured to:
receive the access count value during a normal operation;
compare the received access count value to the ACI flag value; and
initialize the access count value to an initialization value if the received access count value matches the ACI flag value.

2. The apparatus of claim 1, wherein the counter control circuit is further configured to:
receive the access count value when the word line is activated;
iterate the access count value if the access count value does not match the ACI flag value or iterate the initialization value if the received access count value matches the ACI flag value; and
write the iterated access count value or the iterated initialization value back to the counter memory cells of the word line as part of the access count update (ACU) operation.

3. The apparatus of claim 1, wherein the counter individualization circuit comprises a random number generator configured to generate the initialization value.

4. The apparatus of claim 1, wherein the ACI flag value comprises an unnatural counter value.

5. The apparatus of claim 1, wherein the ACI flag value comprises setting all bits of the counter memory cells to 1.

6. The apparatus of claim 1, wherein the initialization value comprises a random number, psuedo-random number, semi-random number, deterministic number, or combinations thereof.

7. The apparatus of claim 1, wherein the initialization value for the word line is an individualized initialization value, wherein the initialization value is different for a second word line.

8. An apparatus comprising:
a memory array comprising a plurality of word lines each associated with one of a plurality of access count values;
an activation counter initialization (ACI) controller configured to provide an address count increment signal and an ACI signal during an ACI mode;
an address counter configured to generate a row address responsive to the address count increment signal;
a row decoder configured to activate one or more of the word lines based on the row address;
a counter control circuit configured to set the plurality of access count values associated with the activated word lines to an ACI flag value responsive to the ACI signal; and
a counter individualization circuit configured to receive an access count value of the plurality of access count values associated with an accessed word line as part of an access count update (ACU) operation and configured to initialize the access count value of the plurality of access count values to an initialization value during the ACU operation if the access count value of the accessed word line is equal to the ACI flag value.

9. The apparatus of claim 8 wherein the counter individualization circuit comprises a random number generator configured to generate the initialization value.

10. The apparatus of claim 8, wherein the counter control circuit increments the access count value associated with the accessed word line if the access count value is different than the ACI flag value.

11. The apparatus of claim 8, wherein the address counter is configured to generate a refresh address when not in the ACI mode.

12. The apparatus of claim 8, wherein the ACI flag value comprises setting all of the bits of the access count value to 1.

13. The apparatus of claim 8, wherein the initialization value is a random number, psuedo-random number, semi-random number, deterministic number, or combinations thereof.

14. A method comprising:
activating a word line of a memory;
reading an access count value along the accessed word line;
comparing the access count value to an ACI flag value;
initializing the access count value to an initialization value if the read access count value matches the ACI flag value.

15. The method of claim 14, further comprising:
iterating the access count value, if the read access count value is different than the ACI flag value.

16. The method of claim 14, further comprising:
powering on the memory device; and
putting the memory device in an ACI mode.

17. The method of claim 16, wherein the memory device in the ACI mode comprises setting the access count value to the ACI flag value.

18. The method of claim 14, further comprising iterating the initialization value.

19. The method of claim 14, wherein the ACI flag value is equal to setting each bit of the access count value to 1.

20. The method of claim 14, wherein the initialization value is a random number, psuedo-random number, semi-random number, deterministic number, or combinations thereof.
